(19) United States
(12) Patent Application Publication
(10) Pub. No.: US 2001/0045591 A1
(43) Pub. Date: Nov. 29, 2001

(54) SEMICONDUCTOR DEVICE AND METHOD OF MANUFACTURING THE SAME

(76) Inventors: YOSHIKAZU TSUNEMINE, HYOGO (JP); MAKOTO MATSUSHITA, HYOGO (JP)

Correspondence Address: MCDERMOTT WILL & EMERY, 600 13TH STREET, N.W., WASHINGTON, DC, 20005-3096, US

(21) Appl. No.: 09/283,245

(22) Filed: Apr. 1, 1999

(30) Foreign Application Priority Data
Oct. 14, 1998 (JP) 10-291850(P)

(51) Int. Cl. H01L 27/108; H01L 29/76

(52) U.S. Cl. 257/306

(57) ABSTRACT

A silicon oxide film in a cylindrical shape which is high in workability as compared with other conductive materials is formed to cover an entire surface of a barrier metal film as a lower electrode of a capacitor. In addition, a sidewall platinum film is formed on side surfaces of silicon oxide film and barrier metal film in the cylindrical shape. Thus, a DRAM having a smaller capacitor with workability of the lower electrode increased and a manufacturing method thereof is provided.

### BACKGROUND OF THE INVENTION

1. Field of the Invention

The present invention relates to semiconductor memory devices and methods of manufacturing the same, and more particularly to a semiconductor memory device provided with a DRAM (Random Access Memory) in which a highly dielectric material is used for a dielectric film of a capacitor and a method of manufacturing the same.

2. Description of the Background Art

Conventionally, a DRAM has generally been known as a semiconductor memory device capable of randomly inputting/outputting storage information. The DRAM is provided with a memory array, which is a storage region for storing a number of pieces of storage information, and a peripheral circuit necessary for externally inputting/outputting.

In addition, a plurality of memory cells are arranged in a matrix for storing unit storage information in a memory cell array which occupies a significant area on a semiconductor chip. Generally, one memory cell includes an MOS (Metal Oxide Semiconductor) transistor and a capacitor connected thereto. Such memory cell is called a memory cell of a single transistor-single capacitor type. The memory cell of this type readily allows increase in an integration degree of the memory cell array because of its simple structure. Thus, it is widely used for DRAMs having large storage capacities.

Memory cells for the DRAM can be classified into several types according to a structure of a capacitor. Included therein is what is called a stacked capacitor. The stacked capacitor allows increase in an area of opposite electrodes of the capacitor by extending a main portion of the capacitor even over a gate electrode or a field oxide film. Having the above mentioned characteristic, the use of the stacked capacitor makes it possible to ensure a given capacitance even when the integration degree of the semiconductor memory device is increased and smaller elements are formed. As a result, the stacked capacitor has become popular with increase in the integration degree of the semiconductor memory device.

When the above mentioned stacked capacitor is used for a DRAM having still smaller elements such as a 256 Mbit DRAM, however, even if the main portion of the capacitor extends over the gate electrode or field oxide film, the area of the capacitor is not as large as what is required because of a small cell area. Thus, it is difficult to ensure a given capacitance for the capacitor.

Then, in order to increase the capacitance without any increase in the area of the capacitor, an attempt has been made to use a dielectric film having a highly dielectric material such as a barium strontium titanate (BST) as a dielectric film of the capacitor. Now, a structure of a DRAM with a stacked capacitor having a memory cell of the DRAM in which a material having a high dielectric constant such as BST is used for a dielectric film of a capacitor will be described with reference to FIG. 22.

As shown in FIG. 22, the conventional DRAM includes an isolation oxide film 102 for isolatively forming an element formation region on a silicon substrate 101. A gate electrode 103 is formed in the element formation region along with a nitride film 104, which covers gate electrode 103. A source/drain region 105 is formed between ends of gate electrode 103 and isolation oxide film 102 to a prescribed depth from a surface of a semiconductor substrate 101. Further, an interlayer oxide film 106 is formed to cover an entire surface.

A barrier metal film 109 including a titanium nitride film is formed on interlayer oxide film 106. Further, a contact plug 108 including a conductive polycrystal silicon which connects source/drain region 105 and barrier metal film 109 is formed such that it passes through interlayer oxide film 106. A platinum film 110 is formed on barrier metal film 109. A sidewall platinum film 112 is formed on side surfaces of platinum film 110 and barrier metal film 109, so that a lower electrode is formed of interlayer oxide film 106, barrier metal film 109, platinum film 110 and sidewall platinum film 112. A BST film 113 having a function of a dielectric film is formed to cover upper surfaces of silicon substrate 101 and platinum film 110 as well as a surface of sidewall platinum film 112. An upper electrode 114 is formed to cover a surface of BST film 113.

A major difference between the DRAM having the above mentioned structure in which the BST film is used as the dielectric film and that using the stacked capacitor which has been mainly used is that noble metal such as platinum is used for an electrode rather than a polycrystal silicon film.

A method of manufacturing a conventional semiconductor memory device will now be described.

First, an isolation oxide film 102 for isolatively forming an element formation region is formed on a silicon substrate 101. A gate electrode 103 is formed in the element formation region along with a nitride film 104 covering gate electrode 103. A source/drain region 105 is formed between ends of gate electrode 103 and isolation oxide film 102 to a prescribed depth from a surface of semiconductor substrate 101. Further, an interlayer oxide film 106 is formed to cover an entire surface.

Then, a conductive barrier metal layer is formed on interlayer oxide film 106. Thereafter, an insulation layer is formed on the barrier metal layer. By dry etching the interlayer oxide layer and insulation layer, a barrier metal film 109 and a platinum film 110 having prescribed shapes are formed. Subsequently, a platinum film is further formed to cover interlayer oxide film 106, barrier metal film 109 including a titanium nitride film and platinum film 110.

Then, by chemically dry etching an upper electrode 114, a sidewall platinum film 112 is formed on side surfaces of platinum film 110 and conductive barrier metal film 109. A BST film 113 is formed to cover an upper surface of platinum film 110 and a surface of sidewall platinum film 112. Then, upper electrode 114 is formed to cover a surface of BST film 113.

In a memory cell of the conventional DRAM, a silicon oxide film obtained by thermally oxidizing silicon or a silicon nitride film formed by a CVD method has been used as the dielectric film. These are both a compound of silicon and could be easily formed on a lower electrode of polycrystal silicon.

However, although a thin film such as the BST film to be used is generally formed by a reactive sputtering method or the CVD method, if the dielectric film including a highly dielectric material such as the BST film is to be formed on the polycrystal silicon film, the polycrystal silicon film which has a higher ionization tendency as compared with noble metal is readily oxidized. Thus, a silicon oxide film is formed on a boundary surface between the dielectric film having BST and the lower electrode including the polycrystal silicon film. The silicon oxide film is low in dielectric constant, so that electric capacitance is significantly reduced.

Then, to avoid the silicon oxide film formed on a boundary surface between the dielectric film having the above mentioned BST film and the lower electrode having the polycrystal silicon film, noble metal such as platinum, which has lower ionization tendency and higher resistance to oxidation as compared with the polycrystal silicon film, is used for the lower electrode. Further, to prevent oxidation of the silicon substrate portion connected to the lower electrode, a conductive barrier metal film (a film for preventing diffusion) for preventing diffusion of silicon and oxygen is used between the lower electrode and a portion including silicon such as the semiconductor substrate.

In the capacitor using the dielectric film having the above mentioned material of high dielectric constant, the shape of the lower electrode including noble metals such as platinum must be obtained by chemical dry etching. However, platinum film 110 of noble metal is difficult to be chemically dry etched, so that a dimension thereof is not well controlled in fine patterning, thereby resulting in a variation of shapes after patterning. As shown in FIG. 23, for example, a platinum film 110 in a trapezoid shape is formed, whose side has a tilt angle of about 60° to 70° with respect to a main surface of silicon substrate 101. The tilt angle in this case is difficult to be controlled to a prescribed value, so that the shape of a fine sidewall platinum film 112 formed on the side surface of platinum film 110 cannot be formed with accuracy. As a result, when platinum film 110 and sidewall platinum film 112 are used for the lower electrode of the fine capacitor, the lower electrode cannot be formed in a prescribed shape. Therefore, as shown in FIG. 24, an area of the lower electrode in contact with BST film 113 which is used as the dielectric film cannot be controlled to achieve a prescribed dimension. As a result, inconveniently, capacitance cannot be controlled to a prescribed value.

Similarly, also in the case where material which is the same as the dielectric material such as the BST film or a titanate lead zirconate film (hereinafter simply referred to as “PZT film”) is used in place of platinum film 110, the BST film or PZT film cannot be formed in a prescribed shape when they are chemically dry etched in a fine capacitor. Thus, sidewall platinum film 12 on a side surface of the BST film or the PZT film cannot be formed in a prescribed shape, so that the area of the lower electrode does not have a prescribed dimension. As a result, inconveniently, capacitance is not controlled to achieve a prescribed value.

Further, even if the shape of the above mentioned platinum film, BST film or PZT film can be controlled, the trapezoid shape is obtained of which side surface having the tilt angle of about 60° to 70° with respect to silicon substrate 101, as shown in FIGS. 23 and 24. Thus, when a height of the trapezoid is to be increased with a given base, the trapezoid may turn to a triangle and the height is not increased anymore.

### SUMMARY OF THE INVENTION

An object of the present invention is to provide a semiconductor memory device provided with a DRAM having a capacitor which has an accurate and large capacitance and which can be fine patterned with enhanced workability of a lower electrode even when noble metal such as platinum must be used for the lower electrode in order to use a material with high dielectric constant such as BST as a dielectric film, and to provide a method of manufacturing the same.

A semiconductor memory device of the present invention includes a capacitor for accumulating signal electric charges having upper and lower electrodes and a capacitor insulation film provided on a semiconductor substrate. The semiconductor memory device includes: a conductive barrier metal film forming a part of the lower electrode and having a side surface; an insulation film including a silicon oxide film or a silicon nitride film formed almost over an entire region of an upper surface of the barrier metal film; a sidewall conductive film formed on side surfaces of the insulation film and barrier metal film and forming part of the lower electrode; a dielectric film formed to be in contact with an upper surface of the sidewall conductive film and forming a capacitor insulation film; and a conductive film formed on a surface of the dielectric film and forming the upper electrode.

In such structure, the insulation film including the silicon oxide film or silicon nitride film is formed on the barrier metal film. Generally, the silicon oxide film or silicon nitride film can readily be kept in a prescribed shape as compared with a material which is difficult to be chemically dry etched such as Pt. Thus, when the sidewall conductive film is applied to the side surfaces of the barrier metal film and insulation film as the lower electrode of the capacitor, the surface area of the sidewall conductive film is at a prescribed value as the sidewall conductive film is kept in a prescribed shape. As a result, a structure of the capacitor readily ensuring a prescribed area for accumulating electric charges is obtained.

In addition, the silicon oxide film or silicon nitride film is formed to have a side surface which is almost perpendicular to a main surface of the semiconductor substrate after etching. As the silicon oxide film or silicon nitride film can be formed with a significant dimension in a direction which is perpendicular to the semiconductor substrate, the sidewall conductive film formed on the side surface of the silicon oxide film or silicon nitride film has a large dimension in the perpendicular direction. Thus, a dimension of the lower electrode of the capacitor is significantly be increased in the perpendicular direction with respect to the semiconductor substrate without any increase in a direction which is parallel to the semiconductor substrate. As a result, the semiconductor memory device provided with a capacitor having a significant capacitance is obtained with a small area when viewed from above.

In the semiconductor memory device according to the present invention, an interlayer insulation film is provided between the semiconductor substrate and the barrier metal film. A contact plug of polycrystal silicon including impurities may be formed to pass through the interlayer insulation film to connect the semiconductor substrate and the barrier metal film.

Such structure prevents diffusion of silicon and oxygen between the contact plug and the sidewall conductive film as the contact plug is connected to the sidewall conductive film through the barrier metal film even when the contact plug is formed of polycrystal silicon. Thus, reduction in conductivity on a boundary surface between the contact plug and the barrier metal film is prevented as the silicon oxide film is formed. As a result, a prescribed capacitance can be achieved for the capacitor.

Further, in the semiconductor memory device according to the present invention, the interlayer insulation film may be a protruding interlayer oxide film having a protruding portion which protrudes from the main surface of the semiconductor substrate, the barrier metal film may be formed over the entire region of an upper surface of the protruding portion, and the sidewall conductive film may be formed continuously to the side surfaces of the insulation film, barrier metal film and protruding portion.

In such structure, the sidewall conductive film is formed not only on the side surfaces of the insulation film and the barrier metal film but also on the side surface of the protruding portion of the interlayer oxide film. Thus, the area of the sidewall conductive film to be a lower electrode of the capacitor is increased by an amount corresponding to the area of the portion formed on the side surface of the protruding portion of the interlayer oxide film. As a result, a large area for accumulation of electric charges can be ensured for the capacitor by increasing a dimension of the structure in a direction which is perpendicular to the main surface of the semiconductor substrate without any increase in a direction in which the main surface of the semiconductor substrate extends.

In the semiconductor memory device according to the present invention, the contact plug may have an exposed portion which is exposed from the surface of the interlayer insulation film, and the protruding portion of the protruding interlayer insulation film may have a sidewall insulation film formed on side surfaces of the barrier metal film and the exposed portion of the contact plug in order to increase a thickness of the barrier metal film continuously from a prescribed position on the side surface of the barrier metal film toward the main surface of the semiconductor substrate. In addition, the sidewall conductive film may be formed on the side surfaces of the insulation film and the barrier metal film and the surface of the sidewall insulation film.

In such structure, the sidewall insulation film is formed to have a tilt angle with respect to the semiconductor substrate such that the thickness thereof continuously increases from the prescribed position on the side surface of the barrier metal film toward the surface of the interlayer insulation film. Thus, the surface area of the sidewall insulation film is increased as compared with the case where it is formed on the sidewall of the protruding portion of the insulation film formed perpendicularly with respect to the semiconductor substrate. Consequently, when the sidewall conductive film is formed on the surface of the sidewall insulation film, a prescribed surface area can be ensured even with the sidewall insulation film having a small base area when viewed from above. As a result, even when the area for accumulation of electric charges of the capacitor is increased, the capacitor is formed with a small area when viewed from above.

In the semiconductor memory device according to the present invention, the dielectric film and the sidewall conductive film may respectively include a material having high dielectric constant and a material having metal which is not readily oxidized as compared with polycrystal silicon.

Generally, when a material having large dielectric constant with a small area is used as the dielectric film, if a material including silicon is used for an electrode, a silicon oxide film is formed and a resistance is generated. When a material including metal which is not readily oxidized as compared with that including silicon is used for the electrode, the above mentioned resistance is not obtained.

However, generally, it is difficult to fine pattern the material including metal which is not readily oxidized as compared with the material including silicon. Then, the above described structure allows the material including metal which is not readily oxidized as compared with that including silicon to be applied onto the sidewall of the insulation film which tends to be in a prescribed shape after patterning. Thus, a capacitor having a prescribed capacitance can readily be formed as the electrode can readily be formed in the prescribed shape.

In the semiconductor memory device according to the present invention, the material having high dielectric constant may include strontium titanate or titanate lead zirconate, and the material having metal may include platinum.

Such structure allows the sidewall conductive film to be formed in a prescribed shape on the side surface of the insulation film which is formed such that an angle between the side and upper surfaces is about 90°, even when platinum with low workability is used in a fine capacitor. As a result, even when platinum in the form of the sidewall conductive film is used as the lower electrode of the capacitor, unlike the material including silicon, the platinum film is not oxidized and the prescribed shape and surface area are obtained for the semiconductor device in which fine patterning is required.

In the semiconductor memory device according to the present invention, the insulation film, contact plug and barrier metal film may be in a cylindrical shape.

Such structure allows the lower electrode to be formed such that the sidewall conductive layer is concentrically around the insulation film, barrier metal film and contact plug in the cylindrical shape, whereby the dielectric film is concentrically formed. Thus, the dielectric film does not have any corner, thereby eliminating a portion where electric field concentrates. As a result, the capacitor is provided with a prescribed capacitance in accordance with a dimension of the area of the dielectric film.

In a method of manufacturing a semiconductor memory device of the present invention, a semiconductor memory device is manufactured which is provided with a capacitor for accumulating signal electric charges having an upper electrode, a lower electrode and a capacitor insulation film provided on a semiconductor substrate. The method includes steps of: forming an interlayer insulation film on the semiconductor substrate; forming a contact hole in the interlayer insulation film; forming a contact plug which includes polycrystal silicon having impurities and forms part of the lower electrode in the contact hole; forming a conductive barrier metal layer on the interlayer oxide film to be in contact with the contact plug; forming an insulation layer including a silicon oxide layer or a silicon nitride layer on the barrier metal layer; forming a barrier metal film forming part of the lower electrode and an insulation film which are in the same prescribed shapes when viewed from above by chemically dry etching the barrier metal and insulation layers; forming a sidewall conductive film which forms part of the lower electrode to cover an upper surface of the interlayer insulation film and surfaces of the barrier metal film and insulation film; forming a dielectric film which forms a capacitor insulation film to cover the surface of the sidewall conductive film and the upper surface of the insulation film; and forming a conductive film which forms an upper electrode on the dielectric film.

The above described steps enables formation of the insulation film on the barrier metal film. Generally, the silicon oxide film or silicon nitride film tends to be maintained in a prescribed shape as compared with a conductive material in a process in which a very small semiconductor memory device is manufactured. Thus, when the sidewall conductive film is applied onto side surfaces of the barrier metal film and the insulation film as the lower electrode of the capacitor, the sidewall conductive film can be maintained in a prescribed shape. Thus, a prescribed capacitance can be ensured for the capacitor. As a result, a semiconductor memory device having a prescribed capacitance can be formed.

In addition, the silicon oxide film or the silicon nitride film are formed to have a side surface which is almost perpendicular to a main surface of the semiconductor substrate. Thus, the silicon oxide film or silicon nitride film can be formed with a large dimension in a direction which is perpendicular to the semiconductor substrate, so that the sidewall conductive film formed on the side surface of the silicon oxide film or silicon nitride film is formed with a large dimension in the perpendicular direction. Thus, the surface area of the lower electrode of the capacitor is increased in the direction which is perpendicular to the semiconductor substrate without any increase in a direction which is parallel to the semiconductor substrate. As a result, the semiconductor memory device with the capacitor having a large capacitance with a small area when viewed from above can be provided.

Even if the contact plug is formed of polycrystal silicon, it is connected to the sidewall conductive film through the barrier metal film, so that diffusion of silicon and oxygen between the contact plug and the sidewall conductive film is prevented. Thus, formation of the silicon oxide film prevents reduction in conductivity on a boundary surface between the conductive plug and the barrier metal film. As a result, the capacitor can be formed in a shape which ensures a prescribed capacitance.

In the method of manufacturing the semiconductor memory device according to the present invention, the step of forming the insulation film and the barrier metal film by etching the insulation layer and the barrier metal layer after the insulation layer is formed further includes a step of forming a protruding interlayer insulation film by overetching the interlayer insulation film such that it has a protruding portion which protrudes from the main surface of the semiconductor substrate. Further, the step of forming the sidewall conductive film on side surfaces of the insulation film and the barrier metal film may include a step of continuously forming the sidewall conductive film on the side surface of the protruding portion.

The steps allows the sidewall conductive film to be formed not only on side surfaces of the insulation film and the barrier metal film but also on the protruding portion of the interlayer oxide film. Thus, the area of the sidewall conductive film which is to be the lower electrode of the capacitor is increased by an amount which corresponds to a portion formed on the side surface of the protruding portion of the interlayer oxide film. As a result, a significant capacitance is ensured as a dimension of the capacitor is increased in a direction which is perpendicular to the main surface of the semiconductor substrate without any increase in a direction in which the main surface of the semiconductor substrate extends.

In the method of manufacturing the semiconductor memory device according to the present invention, the step of forming the contact plug includes a step of forming the contact plug such that it fills the contact hole to a prescribed depth from the surface of the semiconductor substrate. The step of forming the barrier metal layer includes a step of forming the barrier metal film on the contact plug such that a part of the contact hole is filled. The step of forming the insulation layer includes a step of forming an insulation film on the surface of the barrier metal film such that a part of the contact hole is filled and forming a resist on the surface of the insulation film such that a part of the contact hole is filled. The step of overetching the interlayer oxide film includes a step of etching the interlayer insulation film to a prescribed depth from the surface using the resist as a mask and etching the interlayer insulation film such that parts of the insulation film, barrier metal film and contact plug on the upper side are exposed and forming a sidewall insulation film on side surfaces of the exposed portion of the contact plug and of a portion of the barrier metal film on the lower side such that a thickness thereof is continuously increased from the side surface of the portion of the barrier metal film on the lower side. The step of forming the sidewall conductive film may further include a step of forming the sidewall conductive film on the side surfaces of the insulation film and the portion of the barrier metal film on the upper side and the surface of the sidewall insulation film.

The above described steps allows the sidewall conductive film to be formed in a direction which forms a prescribed angle with respect to the semiconductor substrate on the surface of the sidewall insulation film as the sidewall insulation film can be formed such that the thickness thereof is continuously increased from a prescribed position on a side surface of the barrier metal film toward the surface of the interlayer insulation film. Thus, as compared with the case where the sidewall conductive film is formed almost perpendicularly with respect to the semiconductor substrate, a sufficient area of the sidewall conductive film can be ensured even when a base is small. As a result, the capacitor can be formed with a small area when viewed from above even if capacitance is increased.

In the method of manufacturing the semiconductor memory device according to the present invention, the dielectric film and the sidewall conductive film may respectively include a material with high dielectric constant and a material having metal which is not readily oxidized as compared with polycrystal silicon.

The above described steps prevents diffusion of silicon and oxygen between the contact plug and the sidewall conductive film as the contact plug is connected to the sidewall conductive film through the barrier metal film even if the contact plug is formed of polycrystal silicon. Thus, reduction in conductivity on a boundary surface between the contact plug and the barrier metal film is prevented as the silicon oxide film is formed. As a result, the capacitor can be formed in a shape which ensures a prescribed capacitance.

When the material with high dielectric constant in a small area is used as the dielectric film, generally, if a material including silicon is used for an electrode, a silicon oxide film is formed on a boundary surface, thereby generating a resistance. If metal which has low ionization tendency, that is, metal which is not readily oxidized as compared with the material including silicon, is used for the electrode rather than the dielectric film, the above mentioned resistance is not generated. The metal which has low ionization tendency is, however, generally difficult to be fine patterned. Then, the above mentioned step allows formation of the electrode having a prescribed shape by applying metal which is not readily oxidized as compared with the material including silicon to the sidewall of the insulation film which tends to be formed in a prescribed shape by patterning. As a result, the capacitor with a prescribed capacitance can be formed.

In the method of manufacturing the semiconductor memory device according to the present invention, the material with high dielectric constant and the metal material may include strontium titanate or titanate lead zirconate, and platinum, respectively.

The above mentioned step enables formation of the sidewall conductive film in a prescribed shape on the side surface of the insulation film which is formed to have an angle of about 90° between the side surface and the upper surface even when platinum which is low in workability is used in a smaller capacitor. As a result, in the semiconductor memory device which is required to be smaller in size, the sidewall conductive film to be the lower electrode of the capacitor is formed with platinum which is not readily oxidized as compared with silicon, so that the prescribed shape and area are obtained. As a result, the capacitor having a prescribed capacitance can be formed.

In the method of manufacturing the semiconductor memory device according to the present invention, the insulation film, contact plug and barrier metal film may be of a cylindrical shape.

The above mentioned step allows the dielectric film to be concentrically formed as the lower electrode can be formed concentrically around the cylindrical insulation film, barrier metal film and contact plug. Thus, the dielectric film can be formed without any corner, whereby electric field is prevented from concentrating in the dielectric film. As a result, the semiconductor memory device having the capacitor with a prescribed capacitance in accordance with a dimension of an area of the dielectric film can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view showing a semiconductor memory device according to a first embodiment of the present invention.

FIG. 2 is a cross sectional view immediately after a source/drain region is formed in a self-matching manner using a gate electrode and an isolation oxide film as masks in a method of manufacturing the semiconductor memory device according to the first embodiment of the present invention.

FIG. 3 is a cross sectional view immediately after a contact plug is formed in a contact hole which is formed in an interlayer oxide film in the method of manufacturing the semiconductor memory device according to the first embodiment of the present invention.

FIG. 4 is a cross sectional view immediately after a barrier metal layer and an insulation layer are formed in the method of manufacturing the semiconductor memory device according to the first embodiment of the present invention.

FIG. 5 is a cross sectional view immediately after the barrier metal and insulation films are formed by etching the barrier metal and insulation layers in the method of manufacturing the semiconductor memory device according to the first embodiment of the present invention.

FIG. 6 is a cross sectional view immediately after a platinum film is formed to cover the barrier metal and insulation films in the method of manufacturing the semiconductor memory device according to the first embodiment of the present invention.

FIG. 7 is a cross sectional view immediately after a sidewall platinum film is formed by frame etching the platinum film in the method of manufacturing the semiconductor memory device according to the first embodiment of the present invention.

FIG. 8 is a cross sectional view showing a semiconductor memory device according to a second embodiment of the present invention.

FIG. 9 is a cross sectional view immediately after a contact plug is formed in a contact hole which is formed in an interlayer oxide film in a method of manufacturing the semiconductor memory device according to the second embodiment of the present invention.

FIG. 10 is a cross sectional view immediately after barrier metal and insulation layers are formed in the method of manufacturing the semiconductor memory device according to the second embodiment of the present invention.

FIG. 11 is a cross sectional view immediately after barrier metal and insulation layers are etched to form a protruding interlayer oxide film and barrier metal and insulation films are formed in the method of manufacturing the semiconductor memory device according to the second embodiment of the present invention.

FIG. 12 is a cross sectional view immediately after a platinum film is formed to cover a protruding portion of a protruding interlayer oxide film, barrier metal film and insulation film in the method of manufacturing the semiconductor memory device according to the second embodiment of the present invention.

FIG. 13 is a cross sectional view immediately after a sidewall platinum film is formed by frame etching the platinum film in the method of manufacturing the semiconductor memory device according to the second embodiment of the present invention.

FIG. 14 is a cross sectional view showing a semiconductor memory device according to a third embodiment of the present invention.

FIG. 15 is a cross sectional view immediately after a contact plug is formed to a prescribed position in a contact hole formed in an interlayer oxide film in a method of manufacturing a semiconductor memory device according to the third embodiment of the present invention.

FIG. 16 is a cross sectional view immediately after a barrier metal film, insulation film and resist are formed on the contact plug formed in the contact hole in the interlayer oxide film in the method of manufacturing the semiconductor memory device according to the third embodiment of the present invention.

FIG. 17 is a cross sectional view immediately after the contact plug is exposed after etching the interlayer oxide film in the method of manufacturing the semiconductor memory device according to the third embodiment of the present invention.

FIG. 18 is a cross sectional view immediately after an oxide film is formed to cover the barrier metal layer, insulation layer and an exposed portion of the contact plug in the method of manufacturing the semiconductor memory device according to the third embodiment of the present invention.

FIG. 19 is a cross sectional view immediately after a sidewall oxide film is formed by frame etching the oxide film in the method of manufacturing the semiconductor memory device according to the third embodiment of the present invention.

FIG. 20 is a cross sectional view immediately after a platinum film is formed to cover side surfaces of the insulation film and barrier metal film and a surface of the sidewall oxide film in the method of manufacturing the semiconductor memory device according to the third embodiment of the present invention.

FIG. 21 is a cross sectional view immediately after the sidewall platinum film is formed by frame etching the platinum film in the method of manufacturing the semiconductor memory device according to the third embodiment of the present invention.

FIG. 22 is a cross sectional view showing a conventional capacitor in which a platinum film is used as a core of a lower electrode.

FIG. 23 is a cross sectional view showing a core of the lower electrode of the conventional capacitor in which the conventional platinum film is formed in a trapezoid shape.

FIG. 24 is a cross sectional view showing a conventional capacitor in which the platinum film used as a core of the lower electrode is formed in the trapezoid shape.

### DESCRIPTION OF THE PREFERRED EMBODIMENTS

Embodiments of the present invention will now be described with reference to the drawings.

First Embodiment

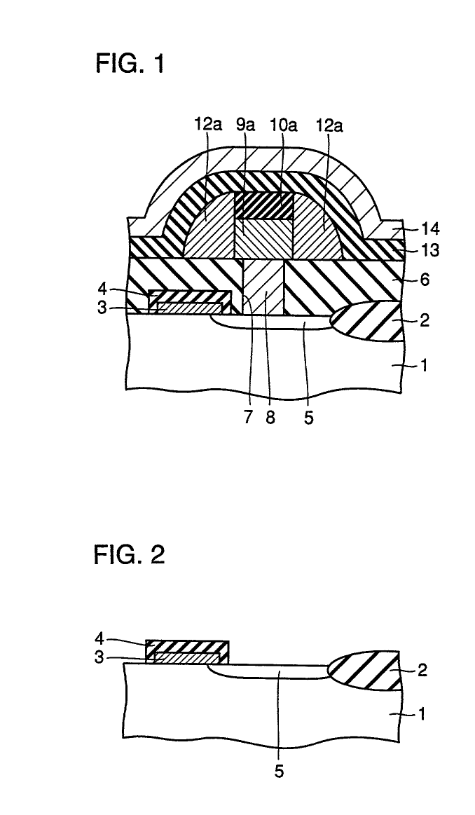

A DRAM according to a first embodiment of the present invention and a manufacturing method thereof will now be described with reference to FIGS. 1 to 7. First, a structure of the DRAM according to the present embodiment will be described. As shown in FIG. 1, the DRAM according to the present embodiment includes an isolation oxide film 2 for isolatively forming an element formation region on a silicon substrate 1. In addition, a gate electrode 3 is formed in the element formation region along with a nitride film 4 covering gate electrode 3. A source/drain region 5 is formed between ends of gate electrode 3 and isolation oxide film 2 to a prescribed depth from a surface of semiconductor substrate 1. An interlayer oxide film 6 is formed to cover an entire surface.

A barrier metal film 9a of a titanium nitride film in a cylindrical shape is formed on interlayer oxide film 6. A contact plug 8 of conductive polycrystal silicon connecting source/drain region 5 and barrier metal film 9a is formed to pass through interlayer oxide film 6.

A silicon oxide film 10a in a cylindrical shape is formed to cover the entire surface of barrier metal film 9a. A sidewall platinum film 12a is provided on side surfaces of silicon oxide film 10a and barrier metal film 9a in the cylindrical shape to have a protruding curved surface from an upper surface of silicon oxide film 10a to a surface of interlayer oxide film 6. A BST film 13 is formed to cover the upper surface of silicon oxide film 10a and the surface of sidewall platinum film 12a. An upper electrode 14 is formed to cover a surface of BST film 13.

In such structure, an angle between side and upper surfaces in a portion to be a core of the capacitor is rendered about 90° with high accuracy as silicon oxide film 10a is used in the portion to be a core of the capacitor. Thus, even when platinum with low workability is used for a smaller capacitor, sidewall platinum film 12a is formed in a prescribed shape on side surfaces of silicon oxide film 10a and barrier metal film 9a formed to have the angle of about 90° between the side and upper surfaces of the core of the capacitor.

Therefore, the prescribed shape and surface area of sidewall platinum film 12a formed on the side surface of silicon oxide film 10a can readily be achieved. Thus, a prescribed area for accumulation of electric charges can readily be ensured for a lower electrode of the capacitor. As a result, even if platinum which is difficult to be fine patterned is used for the lower electrode of the capacitor of the semiconductor memory device which is required to be fine patterned as sidewall platinum film 12a, a stable accumulation amount of electric charges can be obtained.

When a material with high dielectric constant in a small area is used as a dielectric film, if a material including silicon is used for an electrode, a silicon oxide film is disadvantageously formed on a boundary surface, whereby a resistance is generated. Thus, when sidewall platinum film 12a is used for the lower electrode which has low ionization tendency with respect to BST film 13, the above mentioned resistance is not generated.

Sidewall platinum film 12a is, however, generally difficult to be fine patterned. Then, the above described structure allows formation of the lower electrode in a prescribed shape as sidewall platinum film 12a is applied to a side surface of silicon oxide film 10a which tends to be in a prescribed shape after patterning. As a result, a capacitor with a prescribed capacitance is formed.

Even when contact plug 8 is formed of polycrystal silicon, diffusion of silicon and oxygen between contact plug 8 and sidewall platinum film 12a is prevented as contact plug 8 is connected to sidewall platinum film 12a through barrier metal film 9a. Thus, generation of a contact resistance on the boundary surface between contact plug 8 and barrier metal film 9a is prevented as the silicon oxide film is formed on the boundary surface between contact plug 8 and sidewall platinum film 12a. As a result, reduction in conductivity on the boundary surface between contact plug 8 and barrier metal film 9a is prevented, so that the capacitor is provided with a prescribed capacitance.

A sidewall platinum film 12 to be the lower electrode can be formed around silicon oxide film 10a and barrier metal film 9a in the cylindrical shape such that a diameter thereof gradually increases concentrically toward silicon substrate 1. Thus, BST film 13 is also formed on the upper surface of silicon oxide film 10a and the surface of sidewall platinum film 12 such that a diameter thereof gradually increases concentrically toward silicon substrate 1. As a result, BST film 13 does not have any corner, thereby eliminating a portion in which electric field concentrate. As a result, the capacitor is provided with a prescribed capacitance in accordance with a dimension of an area of BST film 13.

Now, a method of manufacturing the DRAM according to the present embodiment will be described with reference to FIGS. 2 to 7.

First, an isolation oxide film 2 for isolatively forming an element formation region is formed on a silicon substrate 1. A gate electrode 3 is formed in the element formation region along with a nitride film 4 covering gate electrode 3. Thereafter, a source/drain region 5 is formed between ends of gate electrode 3 and isolation oxide film 2 to a prescribed depth from a surface of semiconductor substrate 1, as shown in FIG. 2.

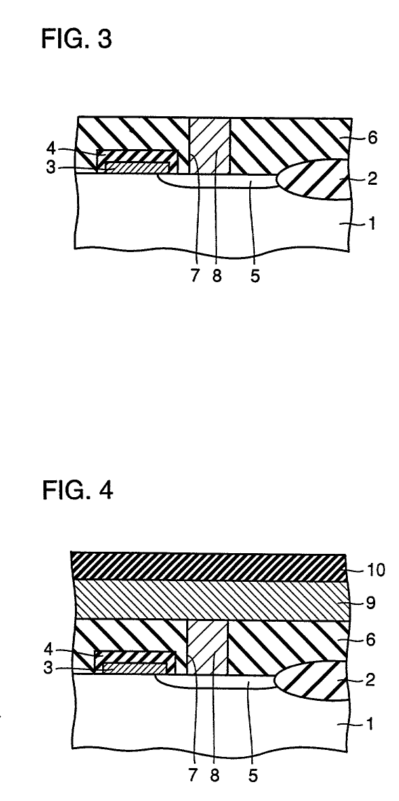

An interlayer oxide film 6 is formed to cover an entire surface. Then, a contact hole 7 is formed to pass through interlayer oxide film 6 and connected to source/drain region 5. Thus, a contact plug 8 including polycrystal silicon fills a contact hole 7 as shown in FIG. 3.

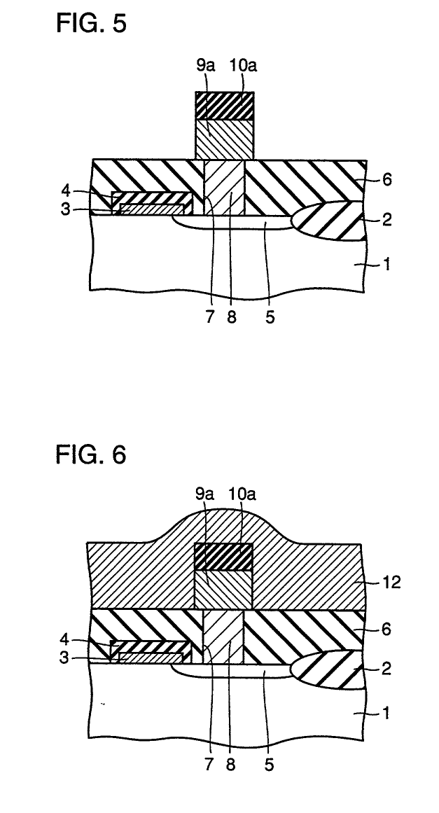

A barrier metal layer 9 including titanium nitride is formed on interlayer oxide film 6. Then, a silicon oxide layer 10 is formed on barrier metal layer 9, as shown in FIG. 4. Thereafter, as shown in FIG. 5, a barrier metal film 9a and a silicon oxide film 10a, which are in a prescribed cylindrical shape and connected to contact plug 8, are formed by chemically dry etching barrier metal layer 9 and silicon oxide layer 10. Subsequently, a platinum film 12 is formed by a sputtering method to cover a surface of interlayer oxide film 6 and side surfaces of barrier metal film 9a and silicon oxide film 10a, as shown in FIG. 6.

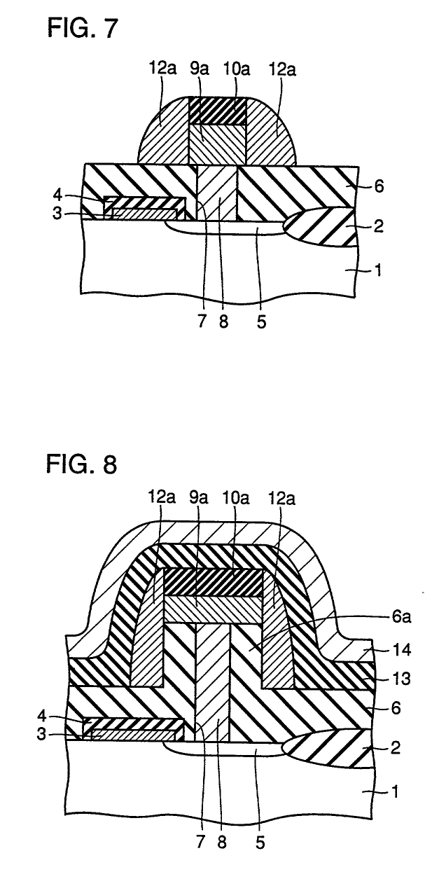

Then, as shown in FIG. 7, by chemically dry etching platinum film 12, a sidewall platinum film 12a is formed on side surfaces of silicon oxide film 10a and conductive barrier metal film 9a in the cylindrical shape. A BST film 13 is formed to cover an upper surface of silicon oxide film 10a and a surface of sidewall platinum film 12a. Then, an upper electrode 14 is formed to cover a surface of BST film 13, whereby a DRAM as shown in FIG. 1 is completed.

Such manufacturing method allows an angle between the side and upper surfaces to be about 90°. Thus, the prescribed shape and surface area of sidewall platinum film 12a formed on the side surface of silicon oxide film 10a can readily be achieved. As a result, even if sidewall platinum film 12a is used for the lower electrode of the capacitor, the capacitor can readily be formed in a shape which ensures a prescribed area of accumulation of electric charges.

In addition, generally, when a material with high dielectric constant with a small area is used for a dielectric film, a silicon oxide film is formed if a material including silicon is used for an electrode, whereby a resistance is generated. The use of sidewall platinum film 12a prevents generation of the above mentioned resistance unlike the case where polycrystal silicon is used.

Sidewall platinum film 12a is, however, generally difficult to be fine patterned. Then, the above described process allows the lower electrode in a prescribed shape to be formed by applying sidewall platinum film 12a on a sidewall of silicon oxide film 10a which can readily be formed in a prescribed shape after patterning. As a result, a capacitor with a prescribed capacitance can be formed.

Even when platinum with low workability is used in a smaller capacitor, sidewall platinum film 12a can be formed in a prescribed shape on the side surface of silicon oxide film 10a which is formed to have an angle of about 90° between the side and upper surfaces. As a result, even when sidewall platinum film 12a, which is difficult to be patterned, is used as the lower electrode of the capacitor in the semiconductor memory device in which fine patterning is required, the prescribed shape and area of sidewall platinum film 12a are achieved. Thus, capacitance of the capacitor can be controlled to a prescribed value.

Even when contact plug 8 is formed of polycrystal silicon, it is connected to sidewall platinum film 12a through barrier metal film 9a, so that diffusion of silicon and oxygen between contact plug 8 of polycrystal silicon and sidewall platinum film 12a is prevented. Thus, generation of a contact resistance is prevented as the silicon oxide film is formed. Consequently, reduction in conductivity on a boundary surface between contact plug 8 of polycrystal silicon and barrier metal film 9a is prevented. As a result, the capacitor is provided with a prescribed capacitance.

As sidewall platinum film 12a to be the lower electrode can be formed concentrically around silicon oxide film 10a and barrier metal film 9a in the cylindrical shape, BST film 13 can be formed concentrically in terms of a cross section which is parallel to silicon substrate 1. Thus, BST film 13 does not have any corner, thereby eliminating a portion in which electric field concentrates. As a result, the semiconductor memory device having the capacitor with a prescribed capacitance in accordance with an area of BST film 13 is provided.

Second Embodiment

A DRAM according to a second embodiment of the present invention and a method of manufacturing thereof will be described with reference to FIGS. 8 to 13. First, a structure of the DRAM according to the present embodiment will be described with reference to FIG. 8. As shown in FIG. 8, the DRAM according to the present embodiment includes an isolation oxide film 2 for isolatively forming an element formation region on a silicon substrate 1. A gate electrode 3 is formed in the element formation region along with a nitride film 4 covering gate electrode 3. A source/drain region 5 is formed between ends of gate electrode 3 and isolation oxide film 2 to a prescribed depth from a surface semiconductor substrate 1. Further, an interlayer oxide film 6 having a protruding portion 6a in a cylindrical shape is formed to cover the entire surface.

A conductive barrier metal film 9a is formed on an upper surface of protruding portion Ga. A contact plug 8 of polycrystal silicon including impurities which connects source/drain region 5 and conductive barrier metal film 9a is formed to pass through interlayer oxide film 6 from the upper surface of protruding portion 6a to a surface of source/drain region 5.

A silicon oxide film 10a is formed on barrier metal film 9a. A sidewall platinum film 12a is formed on side surfaces of silicon oxide film 10a, barrier metal film 9a and protruding portion 9a such that a diameter of the cross section thereof which is parallel to silicon substrate 1 gradually increases concentrically. Further, a BST film 13 is formed to cover an upper surface of silicon oxide film 10a and a surface of sidewall platinum film 12a. An upper electrode 14 is formed to cover a surface BST film 13.

Such structure allows sidewall platinum film 12a to be formed not only on the side surfaces of silicon oxide film 10a and barrier metal film 9a but also on the side surface of protruding portion 6a of interlayer oxide film 6. Thus, an area of sidewall platinum film 12a to be the lower electrode of a capacitor is increased by an amount corresponding to a surface area of a portion formed on the side surface of protruding portion 6a of interlayer oxide film 6. As a result, a significant area for accumulation of electric charges of the capacitor is ensured as a dimension of silicon substrate 1 is increased in a direction which is perpendicular to the main surface of silicon substrate 1 without any increase in a direction which is parallel to the main surface of silicon substrate 1.

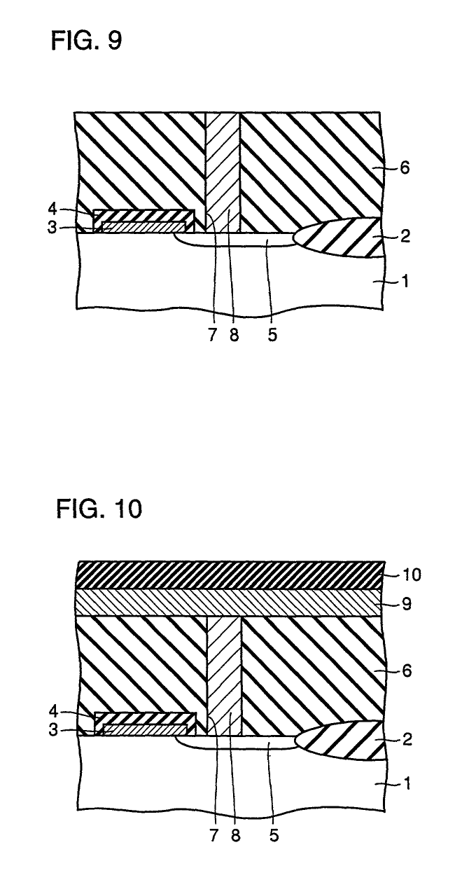

A method of manufacturing the DRAM according to the present embodiment will now be described with reference to FIGS. 9 to 13.

An isolation oxide film 2 for isolatively forming an element formation region is formed on a silicon substrate 1. A gate electrode 3 is formed in the element formation region along with a nitride film 4 covering gate electrode 3. A source/drain region 5 is formed between ends of gate electrode 3 and isolation oxide film 2 to a prescribed depth from a surface of semiconductor substrate 1. An interlayer oxide film 6 is formed to cover the entire surface. Thereafter, a contact hole 7 is formed to be connected to source/drain region 5. A contact plug 8 of a polycrystal silicon film including impurities is filled in contact hole 7, as shown in FIG. 9.

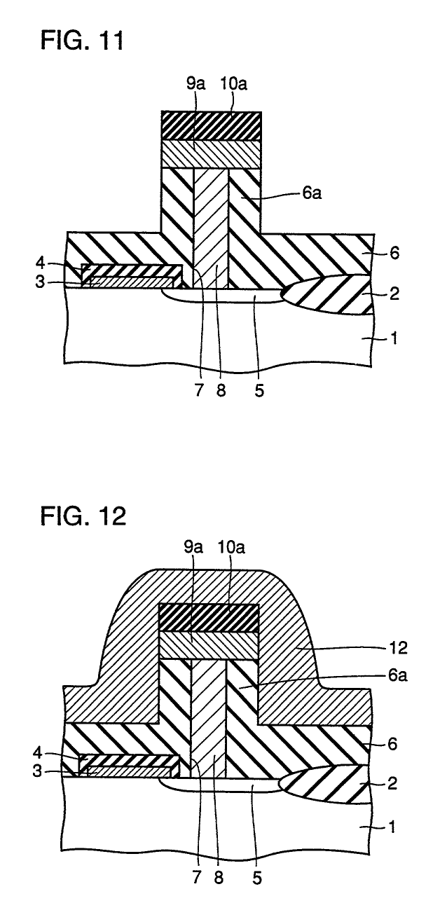

A conductive barrier metal layer 9 is formed on interlayer oxide film 6. Subsequently, a silicon oxide layer 10 is formed on barrier metal layer 9, as shown in FIG. 10. Then, barrier metal layer 9, silicon oxide layer 10 and interlayer oxide film 6 are etched back until interlayer oxide film 6 comes to have a protruding portion 6a in a cylindrical shape, while keeping them in contact with contact plug 8. Thus, as shown in FIG. 11, a barrier metal film 9a and a silicon oxide film 10a in a cylindrical shape are formed.

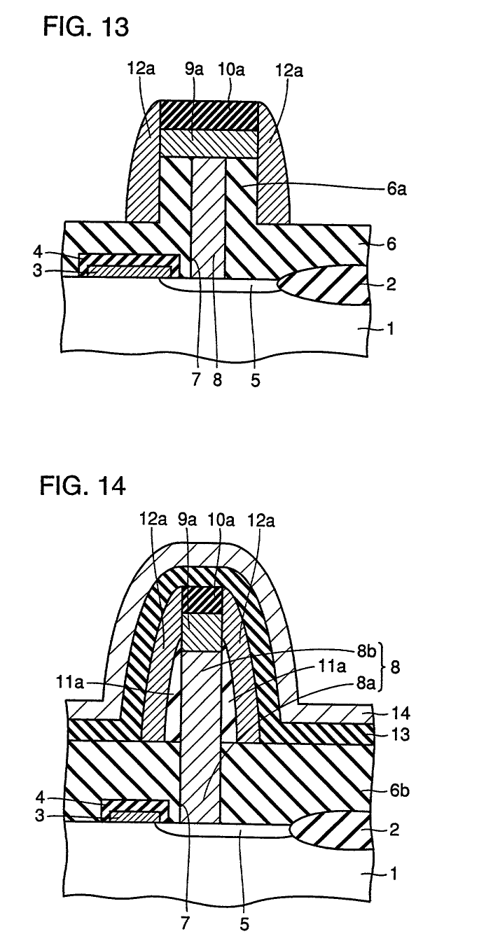

As shown in FIG. 12, a platinum film 12 is deposited on the entire surface by a sputtering method. Then, as shown in FIG. 13, a sidewall platinum film 12a is formed on side surfaces of silicon oxide film 10a, barrier metal film 9a and protruding portion 6a by chemically dry etching platinum film 12. A BST film 13 is formed to cover an upper surface of silicon oxide film 10a and a surface of sidewall platinum film 12a Then, an upper electrode 14 is formed to cover BST film 13 to complete the DRAM shown in FIG. 8.

Such process allows sidewall platinum film 12a to be formed not only on side surfaces of silicon oxide film 10a and barrier metal film 9a but also on the side surface of protruding portion 6a of interlayer oxide film 6. Thus, an area of sidewall platinum film 12a which is in contact with BST film 13 as the lower electrode of the capacitor is increased by an amount corresponding to an area of a portion formed on the side surface of protruding portion 6a of interlayer oxide film 6. As a result, a significant area for accumulation of electric charges of capacitor can be ensured as a dimension is increased in a direction which is perpendicular to a main surface of silicon substrate 1 without any increase in a direction which is parallel to the main surface of silicon substrate 1.

Third Embodiment

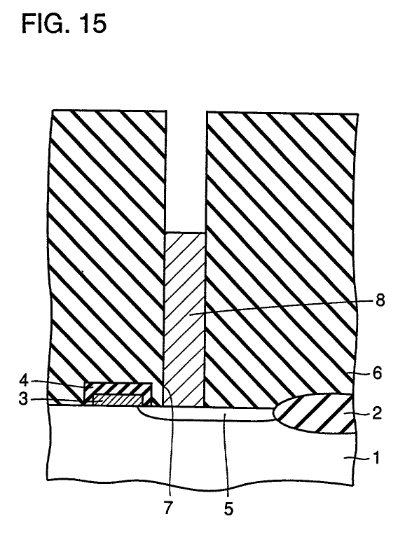

A DRAM according to a third embodiment of the present invention and a method of manufacturing the same will now be described with reference to FIGS. 14 to 21. First, a structure of the DRAM according to the present embodiment will be described with reference to FIG. 14. As shown in FIG. 14, an isolation oxide film 2 for isolatively forming an element formation region is formed on a silicon substrate 1. A gate electrode 3 is formed in the element formation region along with a nitride film 4 covering gate electrode 3. A source/drain region 5 is formed between ends of gate electrode 3 and isolation oxide film 2 to a prescribed depth from a surface of semiconductor substrate 1. Further, an interlayer oxide film 6 is formed to cover the entire surface.

A contact plug 8 of polycrystal silicon including impurities is formed which extends from a prescribed position above a surface of interlayer oxide film 6 to source/drain region 5 through interlayer oxide film 6 and includes an exposed portion 8b and a buried portion 8a. A barrier metal film 9a including titanium nitride is formed on an upper surface of contact plug 8. A silicon oxide film 10a is formed on barrier metal film 9a. A sidewall oxide film 11a is formed such that a diameter thereof is concentrically and gradually increased from side surfaces of exposed portion 8b of contact plug 8 and a portion of a barrier metal film 9a on the lower side toward a surface of silicon substrate 1.

A sidewall platinum film 12a is formed on side surfaces of silicon oxide film 10a and a portion of barrier metal film 9a on the upper side and on the surface of sidewall oxide film 11a. A BST film 13 is formed to cover an upper surface of silicon oxide film 10a and a surface of sidewall platinum film 12a. An upper electrode 14 is formed to cover the surface of BST film 13.

Such structure allows sidewall oxide film 11a to be formed such that a thickness thereof continuously increases from a prescribed position on the side surface of barrier metal film 9a toward the surface of interlayer oxide film 6. Thus, sidewall platinum film 12a is formed to have a prescribed angle with respect to silicon substrate 1 on the surface of sidewall silicon oxide film 10a. Consequently, an area of sidewall platinum film 12a further increases as compared with a case of the second embodiment in which sidewall platinum film 12a is formed on the side surface of protruding portion 6a perpendicularly with respect to silicon substrate 1. As a result, an area for accumulation of electric charges of the capacitor is further increased.

In addition, as sidewall oxide film 11a is formed such that a thickness thereof continuously increases from a prescribed position on the side surface of barrier metal film 9a toward a surface of interlayer oxide film 6, an area of sidewall platinum film 12 in a conical shape when viewed from above is reduced with the same surface area as compared with the second embodiment. As a result, even smaller capacitor is formed.

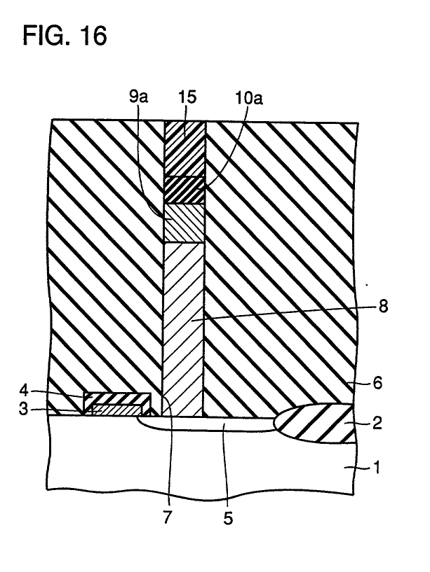

A method of manufacturing the semiconductor memory device according to the present embodiment will now be described with reference to FIGS. 15 to 21.

An isolation oxide film 2 for isolatively forming an element formation region is formed on silicon substrate 1. A gate electrode 3 is formed in the element formation region along with a nitride film 4 covering gate electrode 3. Then, a source/drain region 5 is formed between ends of gate electrode 3 and isolation oxide film 2 to a prescribed depth from a surface of semiconductor substrate 1.

Thereafter, an interlayer oxide film 6 is formed to cover the entire surface. A contact hole 7 is formed passing through interlayer oxide film 6 to a surface of silicon substrate 1. Then, a contact plug 8 of polycrystal silicon including impurities is formed such that it fills contact hole 7 from the surface of silicon substrate 1 to a prescribed height, as shown in FIG. 15.

Then, a conductive barrier metal film 9a is formed on a surface of contact plug 8 such that a portion of contact hole 7 is filled. Thereafter, a silicon oxide film 10a is formed on a surface of barrier metal film 9a such that contact hole 7 is filled to a prescribed height from the lower surface thereof. Then, a resist 15 is formed on a surface of silicon oxide film 10a such that a portion of contact hole 7 is filled, as shown in FIG. 16.

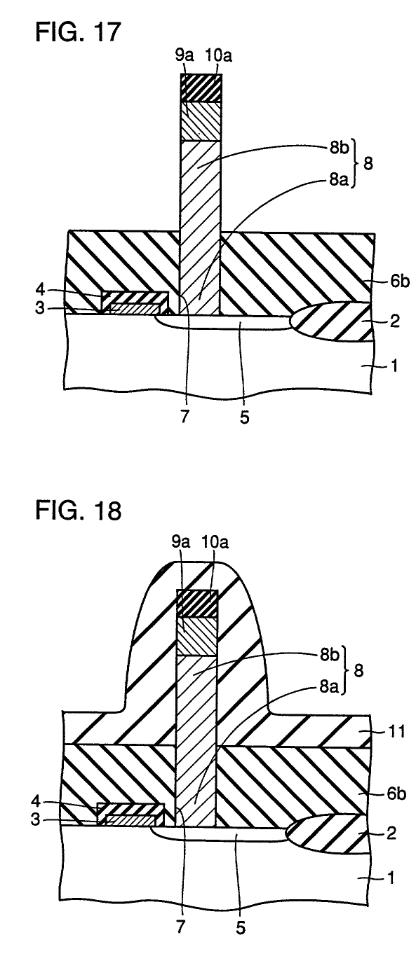

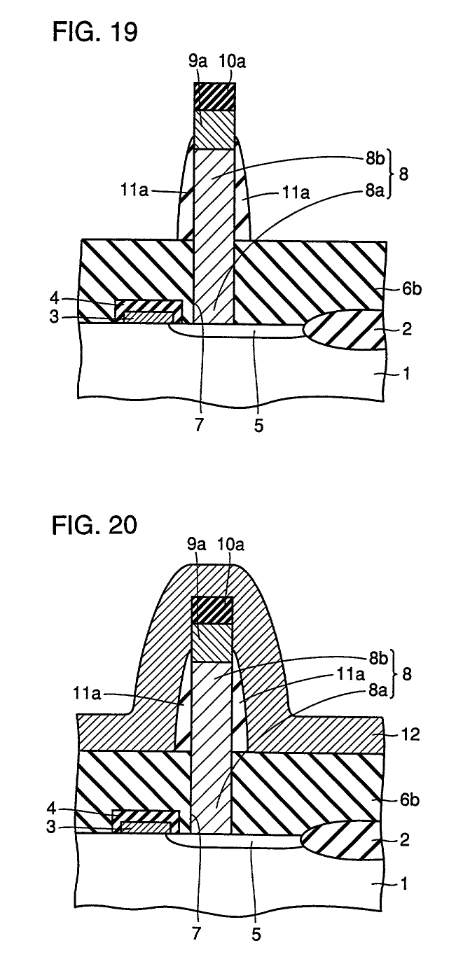

Subsequently, resist 15 is removed after etching interlayer oxide film 6 from the surface thereof to a prescribed depth using resist 15 as a mask, so that interlayer oxide film 6b is formed as shown in FIG. 17. At the same time, silicon oxide film 10a, barrier metal film 9a and an exposed portion 8b of contact plug 8 are exposed. Then, a silicon oxide layer 11 is deposited over the entire surface as shown in FIG. 18. Further, as shown in FIG. 19, a sidewall silicon oxide film 11a is formed on side surfaces of exposed portion 8b of contact plug 8 and a portion of barrier metal film 9a on the lower side such that a diameter thereof continuously increases concentrically from the portion of side surface on the lower side of barrier metal film 9a and the surface of interlayer oxide film 6b in terms of a cross section which is parallel to the main surface of silicon substrate 1.

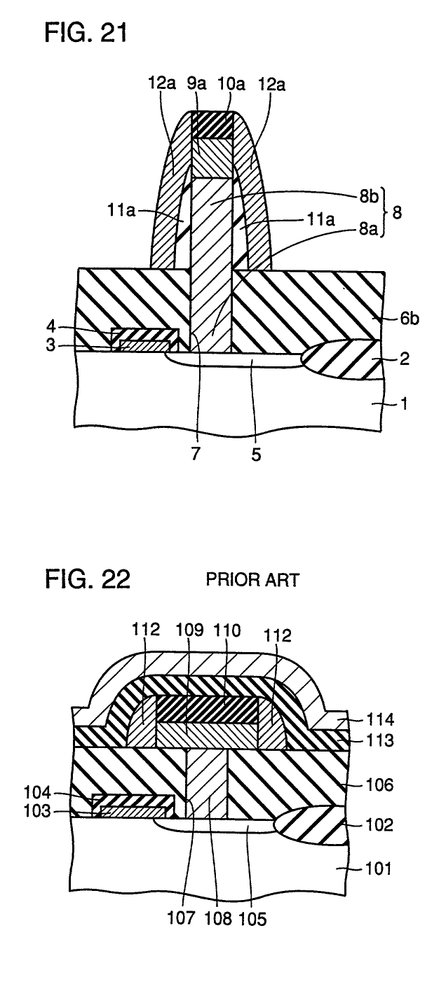

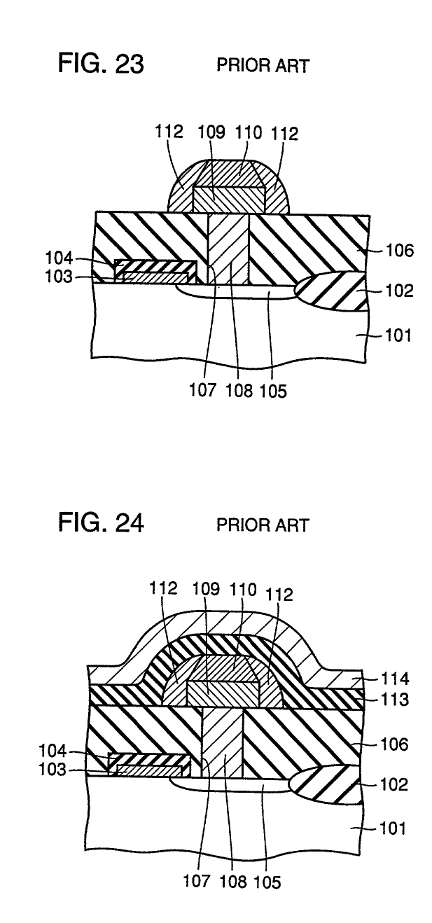

Thereafter, as shown in FIG. 20, a platinum film 12 is deposited over the entire surface by a sputtering method. Then, as shown in FIG. 21, a sidewall platinum film 12a is formed on the side surfaces of silicon oxide film 10a and a portion of barrier metal film 9a on the upper side and the surface of sidewall silicon oxide film 10a. A BST film 13 is formed to cover an upper surface of silicon oxide film 10a and a surface of sidewall platinum film 12a. Subsequently, an upper electrode 14 is formed to cover a surface of BST film 13 to complete the DRAM shown in FIG. 14.

Such process allows sidewall platinum film 12a to be formed to have a prescribed angle with respect to silicon substrate 1 on the surface of sidewall silicon oxide film 10a as sidewall oxide film 11a can be formed such that a diameter thereof is concentrically and gradually increased from a prescribed position on the side surface of barrier metal film 9a toward the surface of interlayer oxide film 6a. Thus, an area of sidewall platinum film 12a is further increased as compared with the case of the second embodiment in which sidewall platinum film 12a is formed almost perpendicularly with respect to silicon substrate 1. As a result, an area for accumulation of electric charges of the capacitor can be further increased.

In addition, as sidewall oxide film 11a can be formed such that the diameter thereof continuously increases from the prescribed position on the side surface of barrier metal film 9a toward the surface of interlayer oxide film 6b, an area of the lower electrode when viewed from above is reduced with the same surface area as compared with the second embodiment. As a result, a smaller capacitor can be formed.

It is noted that, in the above described first to third embodiments, silicon oxide film 10a is employed for a portion which functions as a core for forming sidewall platinum film 12a to be the lower electrode. However, any material such as a silicon nitride film may be used as long as it is high in workability for chemical dry etching.

In addition, although sidewall platinum film 12a is used as the sidewall conductive film in the above described first to third embodiments, any metal such as ruthenium, iridium or palladium may be used as long as it is not readily oxidized even when in contact with the BST film, titanate lead zirconate (PZT) or the like, which is a highly dielectric material.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor memory device provided with a capacitor for accumulation of signal electric charges having upper and lower electrodes and a capacitor insulation film provided on a semiconductor substrate, comprising:
a conductive barrier metal film forming a part of said lower electrode and having a side surface;
an insulation film including a silicon oxide film or a silicon nitride film formed over almost an entire region of an upper surface of said barrier metal film;
a sidewall conductive film formed on side surfaces of said insulation film and said barrier metal film and forming a part of said lower electrode;
a dielectric film formed to be in contact with an upper surface of said sidewall conductive film and forming said capacitor insulation film; and
a conductive film formed on a surface of said dielectric film and forming said upper electrode.

2. The semiconductor device according to claim 1, wherein
an interlayer insulation film is provided between said semiconductor substrate and said barrier metal film, and
a contact plug of polycrystal silicon including impurities is formed to pass through said interlayer insulation film to connect said semiconductor substrate and said barrier metal film.

3. The semiconductor device according to claim 1, wherein
said interlayer insulation film is a protruding interlayer oxide film having a protruding portion protruding from a main surface of said semiconductor substrate,
said barrier film is formed over an entire region of an upper surface of said protruding portion, and
said sidewall conductive film is continuously formed on side surfaces of said insulation film, said barrier metal film and said protruding portion.

4. The semiconductor device according to claim 1, wherein
said contact plug has an exposed portion which is exposed from a surface of said interlayer insulation film,
said protruding portion of said protruding interlayer insulation film has a sidewall insulation film formed on the side surface of said barrier metal film and a side surface of said exposed portion of said contact plug such that a thickness thereof is continuously increased from a prescribed position on the side surface of said barrier metal film toward said main surface of said semiconductor substrate, and
said sidewall conductive film is formed on the side surfaces of said insulation film and said barrier metal film and on a surface of said sidewall insulation film.

5. The semiconductor device according to claim 1, wherein
said dielectric film includes a material with high dielectric constant, and
said sidewall conductive film includes a metal material which is not readily oxidized as compared with polycrystal silicon.

6. The semiconductor device according to claim 1, wherein
said material with high dielectric constant includes barium strontium titanate or titanate lead zirconate, and
said metal material includes platinum.

7. The semiconductor device according to claim 1, wherein
said insulation film, said contact plug and said barrier metal film are in a cylindrical shape.

8. A method of manufacturing a semiconductor memory device provided with a capacitor for accumulation of electric charges having upper and lower electrodes and a capacitor insulation film on a semiconductor substrate, comprising the steps of:
forming an interlayer insulation film on said semiconductor substrate;
forming a contact hole in said interlayer insulation film;
forming a contact plug of polycrystal silicon including impurities forming a part of said lower electrode in said contact hole;
forming a conductive barrier metal layer on said interlayer oxide film to be in contact with said contact plug;
forming an insulation layer including a silicon oxide layer or a silicon nitride layer on said barrier metal layer;
forming a barrier metal film forming the part of said lower electrode and an insulation film in a same prescribed shape when viewed from above by chemically dry etching said barrier metal layer and said insulation layer;
forming a sidewall conductive film forming a part of said lower electrode to cover an upper surface of said interlayer insulation film and surfaces of said barrier metal film and said insulation film;
forming a dielectric film forming said capacitor insulation film to cover a surface of said sidewall conductive film and the upper surface of said insulation film; and
forming a conductive film on said dielectric film forming said upper electrode.

9. The method of manufacturing the semiconductor device according to claim 8, wherein
said step of forming said insulation film and said barrier metal film by etching insulation layer and said barrier metal layer after said insulation layer is formed includes the step of forming a protruding interlayer insulation film by overetching said interlayer insulation film to have a protruding portion protruding from a main surface of said semiconductor substrate while said etching, and
said step of forming said sidewall conductive film on the side surfaces of said insulation film and said barrier metal film includes the step of continuously forming a sidewall conductive film on a side surface of said protruding portion.

10. The method of manufacturing the semiconductor device according to claim 8, wherein
said step of forming said contact plug includes the step of forming said contact plug to fill said contact hole to a prescribed height from a surface of said semiconductor substrate,
said step of forming said barrier metal film includes the step of forming said barrier metal film on said contact plug to fill a portion of said contact hole,
said step of forming said insulation layer includes the step of forming said insulation film on a surface of said barrier metal film to fill a portion of said contact hole and forming a resist on a surface of said insulation film to fill a portion of said contact hole,
said step of overetching said interlayer oxide film includes the step of etching said interlayer insulation film to a prescribed depth from a surface using said resist as a mask, etching said interlayer insulation film such that said barrier metal film, said contact plug and a portion of said contact plug on an upper side are exposed, and forming a sidewall insulation film on a side surface of the portion of said contact plug exposed and on a side surface of a portion of said barrier metal film on a lower side such that a thickness thereof continuously increases from said side surface of the portion on the lower side of said barrier metal film, and
said step of forming said sidewall conductive film includes the step of forming a the sidewall conductive film on the side surface of said insulation film, the side surface of a portion of said barrier metal film on the upper side and the surface of said sidewall insulation film.

11. The method of manufacturing the semiconductor device according to claim 8, wherein
said dielectric film includes a material with high dielectric constant, and
said sidewall conductive film includes a metal material which is not readily oxidized as compared with polycrystal silicon.

12. The method of manufacturing the semiconductor device according to claim 8, wherein said material with high dielectric constant includes barium strontium titanate or titanate lead zirconate, and
said metal material includes platinum.

13. The method of manufacturing the semiconductor device according to claim 8, wherein said insulation film, said contact plug and said barrier metal film have a cylindrical shape.
